(19) United States
(12) Patent Application Publication
(10) Pub. No.: US 2008/0012131 A1
(43) Pub. Date: Jan. 17, 2008

(54) Semiconductor device, mounting construction of a semiconductor device, and method of manufacturing the semiconductor device with the mounting construction

(75) Inventor: Yasuo Tanaka, Tokyo (JP)

Correspondence Address: RABIN & Berdo, PC, 1101 14TH STREET, NW, SUITE 500, WASHINGTON, DC, 20005, US

(73) Assignee: OKI ELECTRIC INDUSTRY CO., LTD, Tokyo (JP)

(21) Appl. No.: 11/723,395

(22) Filed: Mar. 19, 2007

(30) Foreign Application Priority Data
Apr. 12, 2006 (JP) 2006-109595

(51) Int. Cl. H05K 7/02; H01L 23/48

(52) U.S. Cl. 257/738; 257/E23.01

(57) ABSTRACT

A semiconductor pellet is mounted on a circuit board. The pellet has a first terminal pad and a first solder layer formed on the first terminal pad. The circuit board has a second terminal pad and a second solder layer formed on the second terminal pad. A metal ball is positioned between the first and the second solder layers such that when the solder layers are reflowed, an intermetallic compound is formed between the metal ball and the first terminal pad and between the ball and the second terminal pad, the intermetallic compound including a thickness not more than 10 μm in areas in which said metal ball is closest to the second terminal pad and to the first terminal. The metal ball has a surface neither in contact with the first solder layer nor the second solder layer.

### BACKGROUND OF THE INVENTION

1. Field of the Invention

The present invention relates to a semiconductor device, a mounting construction of the semiconductor device, and a method of manufacturing the semiconductor device having the mounting construction.

2. Description of the Related Art

A surface-mounted semiconductor device is electrically connected to a printed circuit board (PCB) by means of solder of a ball grid array (BGA) or a land grid array (LGA). The solder balls are melted by heat to make electrical connection between the semiconductor device and the printed circuit board. The solder balls used in BGA and LGA are provided on terminal pads exposed on the surface of a semiconductor device. The semiconductor device is placed on the printed circuit board such that the solder balls are aligned with corresponding terminal pads on the printed circuit board before the semiconductor device is permanently mounted to the printed circuit board.

Japanese Application Laid-Open No. 2002-261105 discloses one such semiconductor device. Solder is applied to the top of terminal pads by printing or plating.

FIG. 3 is a cross-sectional view of a prior art semiconductor device disclosed in Japanese Application Laid-Open No. 2002-261105, illustrating the electrical connection between the terminal pad and solder. This semiconductor device takes the form of a semiconductor device in a BGA package. The semiconductor device incorporates a chip sealed with a resin using a technique called a wafer-level chip size package (CSP).

This semiconductor device includes a chip 111 having a substrate on which various circuit elements are fabricated, an electrically conductive layer formed on the upper surface of the substrate, an insulating layer formed on the upper surface of the electrically conductive layer, and others. The upper surface of the chip 111 is sealed with a resin layer 113. The resin layer 113 incorporates a terminal pad 115. The top surface of the terminal pad 115 is exposed on the upper surface of the resin layer 113. Electrical connection between the semiconductor device and the printed circuit board is made through the exposed surface of the terminal pad 115.

The terminal pad 115 is electrically connected to the chip 111 through wiring (not shown), commonly Cu.

A flux 117 is printed on the terminal pad 115 and a solder ball 119 is mounted onto the flux 117 in a direction shown by arrow A. The solder ball 119 includes a spherical metal ball 121 made of, for example, Cu and solder 123 that covers the surface of the metal ball 121.

FIGS. 4A-4D illustrate the respective stages of a method for manufacturing a prior art semiconductor device. The manufacturing stages of the aforementioned conventional semiconductor device will be described with reference to FIGS. 4A-4D.

A chip 11 of semiconductor has a resin layer 113 in which the terminal pad 115 is embedded (FIG. 4A). The chip 111 includes, for example, a substrate, wiring, a required electrically conductive layer, an insulating layer formed on the electrically conductive layer. The terminal pad 115 is formed on the chip 111. The resin layer 113 is formed on the chip 111 in contact with the terminal pad 115, and surrounds the terminal pad 115. The top surface of the terminal pad 115 is substantially flush with that of the resin layer 113, and is exposed. The top surface of the terminal pad 115 is covered with an oxide film of metal (e.g., Cu) formed due to direct contact with the air.

A flux 117 is applied to the top surface of the terminal pad 115 (FIG. 4B), being effective in removing the oxide film to make electrical connection between the solder 123 and the terminal pad 115.

Then, a solder ball 119 is mounted onto the flux 117 in a direction shown by arrow B. The solder ball 119 includes the spherical metal ball 121, and the solder 123 that covers the entire surface of the metal ball 121. The metal ball 121 usually takes the form of a Cu ball.

Conventionally, the solder used for the solder ball 119 is made of a material that contains Pb, e.g., Sn—Pb. “Sn—Pb” solder implies a mixture of Sn and Pb or a mixture of Sn, Pb, and several weight percent to several tens weight percent of additional materials.

Solder that contains Pb is detrimental to the environment. For example, use of this type of solder began to be restricted since it may corrode seriously the semiconductor manufacturing apparatus. Thus, recently, Pb solder is being replaced by Pb free solder. The most common Pb free solder is Sn—Ag—Cu solder that contains a mixture of Sn, Ag, and Cu.

Then, the chip 111 is subjected to a heat treatment (referred to as reflow process hereinafter) where the chip 111 is placed on a conveyer belt and is conveyed through a tunnel-type furnace such that the solder 123 of the solder ball 119 is reflowed (FIG. 4D).

In the solder reflow furnace, the solder 123 is melted to form a BGA that makes electrical connection to the terminal pad 115.

The solder 123 reacts with Cu of the terminal pad 115 into an intermetallic compound (not shown). For example, if the solder 123 is Sn—Pb solder or Sn—Ag-Cu solder, a reaction product of Cu and Sn (referred to as Cu—Sn reaction product hereinafter), e.g., Cu₆Sn₅ is formed.

An LGA semiconductor device may also be manufactured in much the same processes as those in FIGS. 4A-4D.

The aforementioned manufacturing method used for the chip 111 which is resin-sealed in a wafer level CSP may also be applied to flip-chip type semiconductor devices.

When the semiconductor device is assembled to the printed circuit board, the solder of the BGA and LGA is melted to make electrical connection with the terminal pads of a printed circuit board.

The mounting construction for mounting the aforementioned semiconductor device on a printed circuit board will be described. FIGS. 5A and 5B are cross-sectional views of the semiconductor device.

Referring to FIG. 5A, a terminal pad 129 is formed at a predetermined position on a printed circuit board 127. Just as the terminal pad 115, the terminal pad 129 is commonly made of Cu.

The semiconductor device 125 and the printed circuit board 127 are arranged such that the solder 123 directly faces the terminal pad 129 (FIG. 5A).

The BGA is melted in a reflow process such that the solder 123 melts to make metallurgical bonding of the metal ball to the terminal pad 129 (FIG. 5B).

During the reflow process, the solder 123 reacts with Cu of the terminal pad 129 to produce an intermetallic compound (not shown). When the solder 123 is Sn—Pb solder or Sn—Ag—Cu solder, Cu reacts with Sn to produce Cu₆Sn₅ as an intermetallic compound.

As described above, the BGA- or LGA-semiconductor device is mounted on the printed circuit board.

The aforementioned prior art semiconductor device suffer from a drawback in that bonding of the terminal pad to solder is not very reliable.

The metallurgical bonding of solder to the terminal pad of a semiconductor device is subjected to heat stress as follows:

(A) When the semiconductor manufacturing is manufactured, the semiconductor is subjected to heat stress during the reflow process where the solder of a semiconductor device is heated, and is then cooled.

(B) When the semiconductor device is mounted on a printed circuit board, the semiconductor is subjected to heat stress during the reflow process where the solder of the semiconductor device is heated and is then cooled. (C) The bonding of the terminal pads and solder of the semiconductor device is subjected to heat stress every time the electronic apparatus is turned on and off.

The heat stresses (A)-(C) may cause metallurgical bonding of the solder to the terminal pads of the semiconductor device and the metallurgical bonding of the semiconductor device to the terminal pads of the printed circuit board to become cracked for the following reasons.

Trend in recent years is that semiconductor devices have closely pitched terminals and an overall thin structure. Consequently, the semiconductor devices have smaller terminal diameters and short heights of terminals. Smaller diameters and shorter heights of terminals lead to smaller spaces between the solder and terminal pads. Thus, heat stress due to the reasons (A)-(C) may concentrate on an area between the top surface of the terminal pad 115 and the metal ball and an area between the metal ball and the printed circuit board 127, leading to occurrence of cracks in these areas.

A crack is a source of poor bonding of solder to the terminal pad.

For the aforementioned reasons, the prior art semiconductor device has poor reliability in bonding of solder to the terminal pads.

### SUMMARY OF THE INVENTION

An object of the invention is to provide a semiconductor with terminal pads and solder where the terminal pads and solder are in metallurgical bonding, a manufacturing method for manufacturing the semiconductor, and a mounting construction for mounting the semiconductor device on a printed circuit board.

A semiconductor device includes a base and a first terminal pad formed on the base. A first solder layer is formed on the first terminal pad. A metal ball is mounted to the first terminal pad by the first solder layer, and has a first surface covered with the first solder layer. The distance between the metal ball and the first terminal pad is less than or equal to 10 μm in a first area in which the metal ball is closest to said first terminal pad.

An intermetallic compound is formed in the first area.

The metal ball, the first solder layer, and the first terminal pad react with one another to form the intermetallic compound.

The first solder layer is an Sn—Ag—Cu solder, and the first terminal pad and the metal ball are formed of copper, wherein the intermetallic compound is Cu₆Sn₅.

The metal ball may be formed of nickel (Ni).

The metal ball may be formed of tungsten (W).

The metal ball 21 has a degree of purity higher than 99.99%.

A mounting structure for a semiconductor device includes a base, a circuit board, a first solder layer, and a metal ball. The base has a first terminal pad. The circuit board has a second terminal pad. The first solder layer is formed on the first terminal pad. The second solder layer is formed on the second terminal pad. The metal ball is positioned between the base and the circuit board, and is mounted to the first terminal pad by the first solder layer and to the second terminal pad by the second solder layer. The metal ball has a first surface covered with the first solder layer, a second surface covered with the second solder layer, and a third surface exposes a surface of the metal ball. The distance between the metal ball and the first terminal pad is less than or equal to 10 μm in a first area in which the metal ball is closest to the first terminal pad. The distance between the metal ball and the second terminal pad is less than or equal to 10 μm in a second area in which the metal ball is closest to the second terminal pad.

The metal ball, the first solder layer, and the first terminal pad react with one another to form an intermetallic compound. The metal ball, the second solder layer, and the second terminal pad react with one another to form an intermetallic compound.

The intermetallic compound fills in the first area and in the second area.

The second solder layer is an Sn—Ag—Cu solder. The second terminal pad and the metal ball may be formed of Cu. The intermetallic compound may be Cu₆Sn₅.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus are not limiting the present invention, and wherein:

FIGS. 1A-1D are cross-sectional views illustrating respective stages of a method for manufacturing a semiconductor device;

FIGS. 2A-2D are cross-sectional views illustrating various manufacturing stages;

FIG. 3 is a cross-sectional view of a prior art semiconductor device illustrating the connection between a terminal pad and solder;

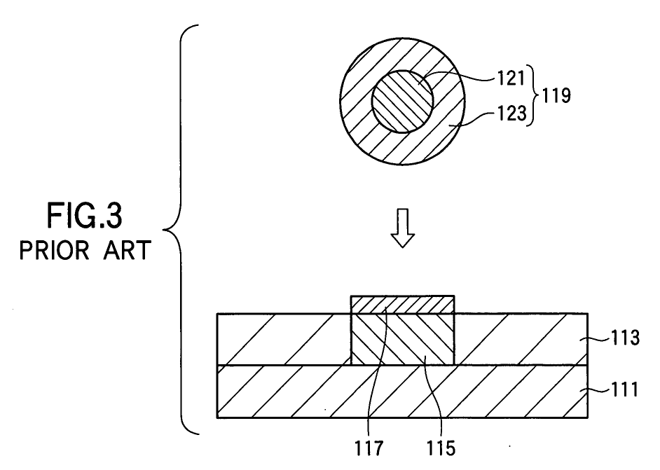

FIGS. 4A-4D illustrate respective stages of a prior art method for manufacturing the prior art semiconductor device; and

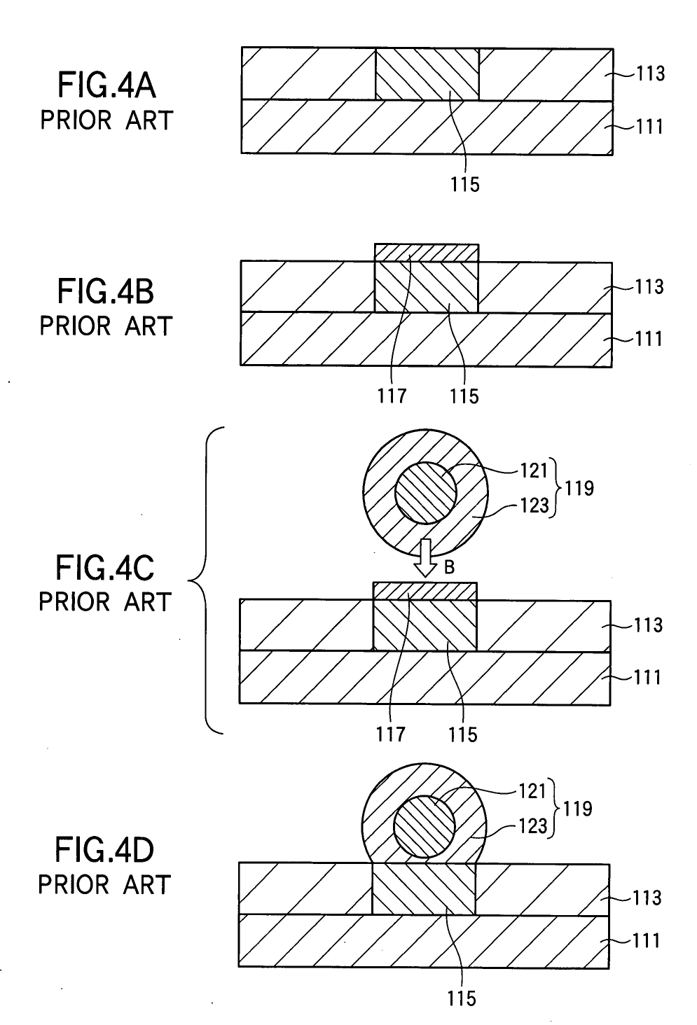

FIGS. 5A and 5B are cross-sectional views of the prior art semiconductor.

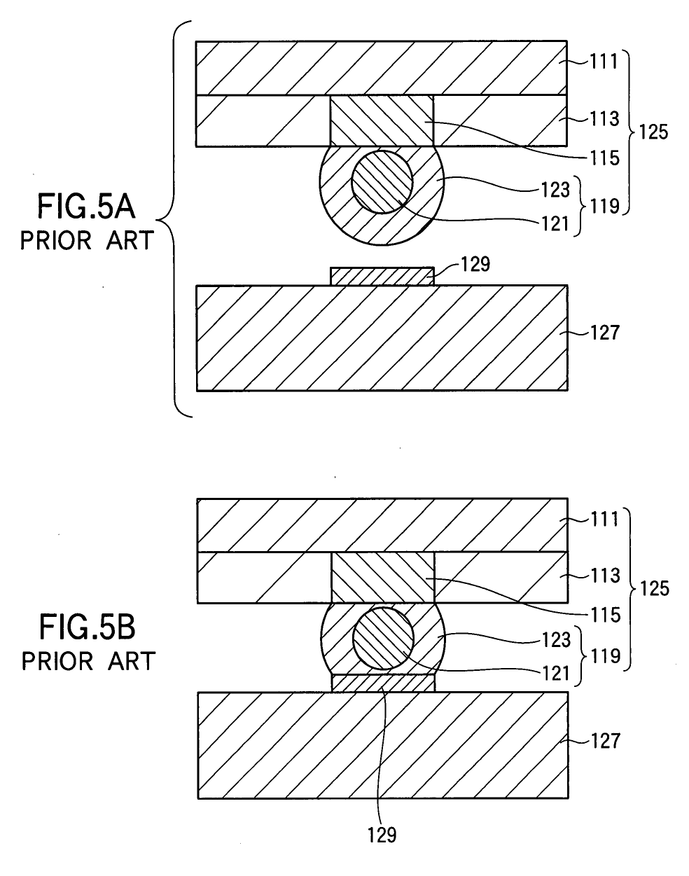

### DETAILED DESCRIPTION OF THE INVENTION

Embodiments of the present invention will be described with reference to the accompanying drawings. The shape, relative size, and location of the respective elements are diagrammatically shown for the purposes of illustration only. Therefore, it is to be noted that the present invention is not limited to the illustrated configurations.

### First Embodiment

A semiconductor device of a first embodiment includes a first embodiment includes a first terminal pad, a metal ball, and a first solder layer that makes metallurgical bonding of the first terminal pad to the metal ball. A method for manufacturing the semiconductor device will be described. The method includes first to fourth stages.

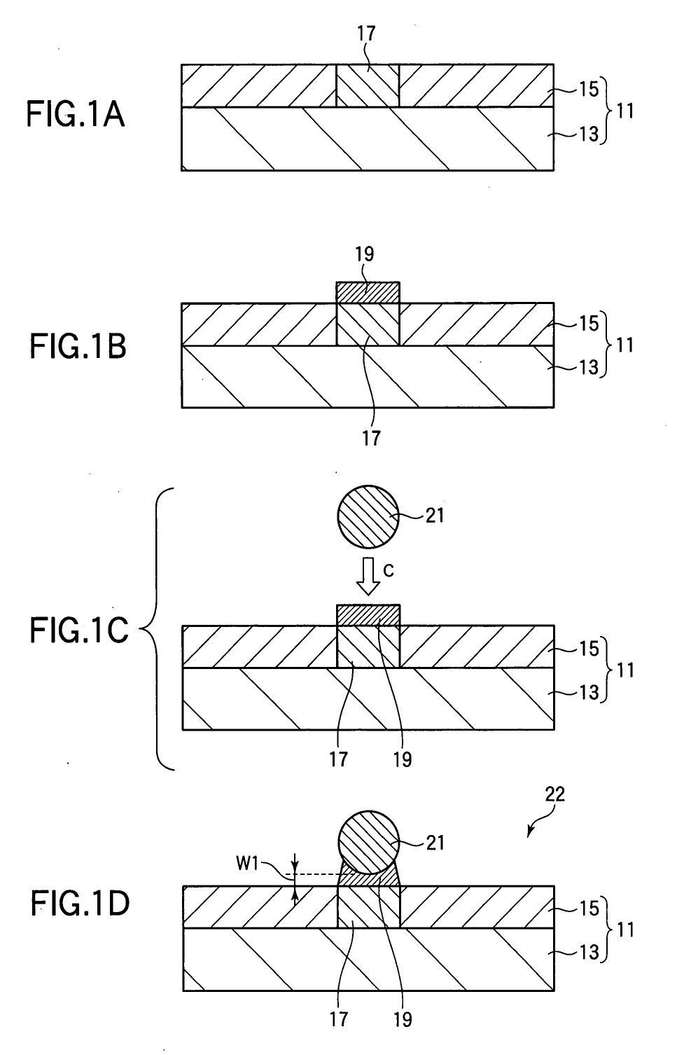

FIGS. 1A-1D are cross-sectional views illustrating the respective stages of the method.

At the first stage (FIG. 1A), a pellet 11 is prepared which includes a chip 13 and a resin layer 15 in which a first terminal pad 17 is formed.

The pellet 11 is a well known pellet in the art. The pellet 11 of the first embodiment is one in a CSP package.

The chip 13 includes a substrate on which various elements are fabricated, an electrically conductive layer formed on the upper surface of the substrate, an insulating layer formed on the upper surface of the electrically conductive layer, and others. The top surface of the chip 13 is sealed with the resin layer 15. The resin layer 15 includes the first terminal pad 17 formed therein, the top surface of the first terminal pad 17 being exposed on the upper surface of the resin layer 15.

The first terminal pad 17 is electrically connected to the chip 13 by wiring (not shown). As is well known in the art, the first terminal pad 17 is made of an electrically conductive metal, e.g., Cu. The top surface of the terminal pad 17 is covered with an oxide film (not shown) of metal, e.g., Cu, due to direct contact with the air.

At the second stage, the first solder layer 19 is formed on the top surface of the first terminal pad 17, thereby forming a pellet as shown in FIG. 1B.

The first solder layer 19 is formed by supplying solder paste using a conventional printing technique. This solder paste is a mixture of approximately 10% by weight of a flux, several percent by weight of rosin, approximately 1% by weight of an activator, several percent by weight of an alcoholic solvent, and a remaining percent by weight of solder.

The flux in the solder paste serves to remove the oxide film covering the first terminal pad 17, facilitating bonding of the first solder layer 19 to the first terminal pad 17. The solder is, for example, Sn—Ag—Cu solder, and preferably contains by 96.5% by weight of Sn, 3.0% by weight of Ag, and 0.5% by weight of Cu. These proportions expressed in weight percent should meet the following requirements.
(1) The metal ball and the first terminal are electrically connected in the succeeding third and fourth stages.
(2) The flux removes the oxide film to promote metallurgical bonding of the first solder layer 19 to the first terminal pad 17.

The above materials contained in the solder paste may be combined in any proportions as long as the aforementioned requirements are met.

Adjusting the amount of the solder paste allows adjustment of the thickness of the first solder layer 19. By adjusting the thickness of the first solder layer 19, the first solder layer 19 may be formed at the third and fourth stages such that the metal ball 21 to be bonded to the first solder layer 19 is present in an area where heat stress is concentrated, e.g., an area into which cracks in the first solder layer 19 may propagate. The amount of the first solder layer 19 should be adjusted such that the thickness of the first solder layer 19 is preferably a maximum of 10 min an area where the distance between the metal ball and the top surface of the first terminal pad 17 is a minimum. A thickness not more than 10 μm ensures that the first solder layer 19 is formed such that an intermetallic compound fills an area into which cracks in the first solder layer 19 may propagate. However, the distance may deviate from 10 μm as long as the aforementioned requirements are met.

At the third stage, a metal ball 21 is mounted in a direction shown by arrow C onto the first solder layer 19 formed at the second stage (FIG. 1C).

The metal ball 21 may be formed of, for example, Cu, Ni, W, or any suitable metal depending on the specific design. The metal ball 21 should preferably have a degree of purity higher than or equal to 99.99%. A degree of purity higher than 99.99% is necessary for improving the quality of an intermetallic compound produced in the boundary of the metal ball 21 and the first solder layer 19. This intermetallic compound is a compound, e.g., Cu₆Sn₅, produced when the metal ball (e.g., Cu) reacts with the solder (Sn—Ag—Cu solder) of the first solder layer 19. A low degree of purity of the metal material of the metal ball 21 causes Kirkendall voids, leading to cracks in the solder layer 19.

The intermetallic compound of the metal ball 21 and the first solder layer 19 has a thickness in the range of 1 to 5 μm. Likewise, the intermetallic compound of the terminal pad 17 and the first solder layer 19 has a thickness in the range of 1 to 5 μm. When heat is applied to the intermetallic compound, the intermetallic compound grows in thickness to about 10 μm or more.

A solder layer is soft and therefore it is easy for cracks to propagate through the solder layer. On the other hand, an intermetallic compound has a high hardness and therefore it is difficult for cracks to propagate through the intermetallic compound.

Thus, if an intermetallic compound is formed to fill the narrow area between the metal ball 21 and the first solder layer 19, the intermetallic compound resists the propagation of cracks. If only the intermetallic compound fills the area between the metal ball 21 and the first terminal pad 17 and no solder alloy is present in the area, the intermetallic compound effectively prevents the propagation of cracks.

In order to prevent cracks from occurring in the area between the metal ball 21 and the first terminal pad 17 or cracks in the solder layer from propagating into the area between the metal ball 21 and the first terminal pad 17, the metal ball 21 should be formed of a metal having a high purity. Degrees of purity not smaller than 99.99% are sufficient to prevent Kirkendall voids from being formed in the intermetallic compound. However, the purity is not limited to 99.99% and may be in the vicinity of 99.99% or in other range as long as Kirkendall voids are not caused.

The metal ball 21 is substantially spherical, and is placed on the first solder layer 19. The surface of the metal ball 21 except for that in contact with the first solder layer 19 is exposed, i.e., not covered with solder.

The metal ball 21 may be a one that is thinly plated, e.g., flush plating, to avoid oxidation.

At the fourth stage, the first solder layer 19 is reflowed during heat treatment such that the metal ball 21 is be bonded to the first terminal pad 17, thereby producing a semiconductor device 22 illustrated in FIG. 1D.

The reflow process in which the first solder layer 19 is melted may be a conventional one. The temperature and the amount of time for the reflow process may be selected in accordance with the melting point of the solder paste that forms the first solder layer 19. For Sn—Ag—Cu solder, the first solder layer 19 is preheated at a temperature in the range of 15-220° C. for 90-120 seconds, and then heated at 220-250° C. for 20-30 seconds, thereby completing the reflow process.

After the reflow process, the first solder layer 19 is cooled to solidify again. The heating process and solidification of the first solder layer 19 causes metallurgical bonding of the metal ball 21 to the first terminal pad 17. The metal ball 21 is used for external electrical connection to a printed circuit board.

As described previously, the first solder layer 19 has been adjusted in thickness at the second stage such that only the intermetallic compound fills an area between the metal ball and the first terminal pad 17 and no solder layer is present in the area. Specifically, the thickness W1 (FIG. 1D) of the first solder layer is a maximum of 10 μm in an area where the metal ball 21 is closest to the first terminal pad 17.

The semiconductor device 22 of the first embodiment is provided with the metal ball 21 on the first terminal pad 17, the metal ball 21 being used for connection with external components such as a printed circuit board. The metal ball 21 is not covered with solder as opposed to a conventional solder ball whose surface is covered with solder in its entirety. The metal ball 21 of the embodiment is bonded to the first terminal pad 17 with the first solder layer 19 positioned between the metal ball 21 and the first terminal pad 17. Because the metal ball 21 is not covered with solder as opposed to a conventional metal ball enclosed entirely by solder, the thickness of the intermetallic compound may be not more than 10 μm regardless of the size of the semiconductor device, as opposed to amounting construction using a conventional solder ball covered with solder in its entirety. In other words, the semiconductor device of the first embodiment is such that the thickness of the first solder layer 19 is selected such that the intermetallic compound is present in an area where heat stress is concentrated, i.e., an area into which the cracks propagate through the first solder layer 19.

Because the distance W1 is a maximum of 10 μm, the intermetallic compound completely fills the area of W1, preventing the cracks in the first solder layer 19 from propagating into the area of W1. Thus, the intermetallic compound of a maximum of 10 μm is effective in retarding propagation of the cracks in the first solder layer 19 which would otherwise occur due to the heat stress during the reflow process performed when the semiconductor device is mounted on the printed circuit board, or the heat stress encountered every time an electronic circuit on the printed circuit board starts to operate and stops operating. Therefore, the terminal pad may be bonded to the solder properly so that bonding reliability is much more improved compared to the conventional art.

At the second stage, the first solder layer 19 is formed on the upper surface of the first terminal pad 17. At the third stage, the metal ball 21 is placed on the first solder layer 19. It is to be noted that the metal ball placed on the first terminal pad is not a one enclosed entirely by the solder layer. Instead, the metal ball is mounted on the pellet 11 at a stage different from the stage at which the solder layer is formed. This is advantageous in that the thickness of the intermetallic compound may be not more than 10 μm regardless of the size of a semiconductor device. Moreover, the thickness of the solder layer 19 is adjusted such that the intermetallic compound is formed in an area into which the cracks in the first solder layer 19 tend to propagate due to heat stress.

Specifically, the thickness W1 of the first solder layer 19 is a maximum of 10 am in an area where the metal ball 21 is closest to the first terminal pad 17. Even when the semiconductor device is subjected to heat stress during the reflow process at the fourth stage where the first solder layer is heated and then cooled, the intermetallic compound effectively retards propagation of the cracks in the first solder layer 19. This improves bonding effect of the solder to the terminal pad.

The first embodiment has been described with respect to a pellet 11 in a CSP package. The method of manufacturing a semiconductor device of the first embodiment may also be applied to a pellet not having the resin layer 15, e.g., a flip-chip type pellet.

The method for manufacturing the semiconductor device will be summarized as follows:

Step 1: A pellet 11 is prepared which includes a terminal pad 17 formed on a surface of the pellet.

Step 2: A solder layer 19 is formed on the terminal pad 17.

Step 3: A metal ball 21 is placed on the solder layer 19.

Step 4: The pellet 11 is subjected to a reflow process such that the metal ball 21, the first solder layer 19, and the terminal pad 17 react with one another to form an intermetallic compound that fills in an area between the metal ball 21 and the terminal pad 17.

At step 2, the thickness of the solder layer is selected such that the distance between the metal ball 21 and the terminal pad 17 is less than or equal to 10 μm in an area in which the metal ball 21 is closest to the terminal pad 17.

### Second Embodiment

A second embodiment is directed to a mounting construction in which a semiconductor device manufactured in the first embodiment is assembled to a printed circuit board. Elements similar to those in the first embodiment have been given the same reference numerals and their description is omitted.

The method for manufacturing a semiconductor device of the second embodiment includes the first to fourth stages of the first embodiment and additional fifth to eighth stages. The method will be described beginning with the fifth stage.

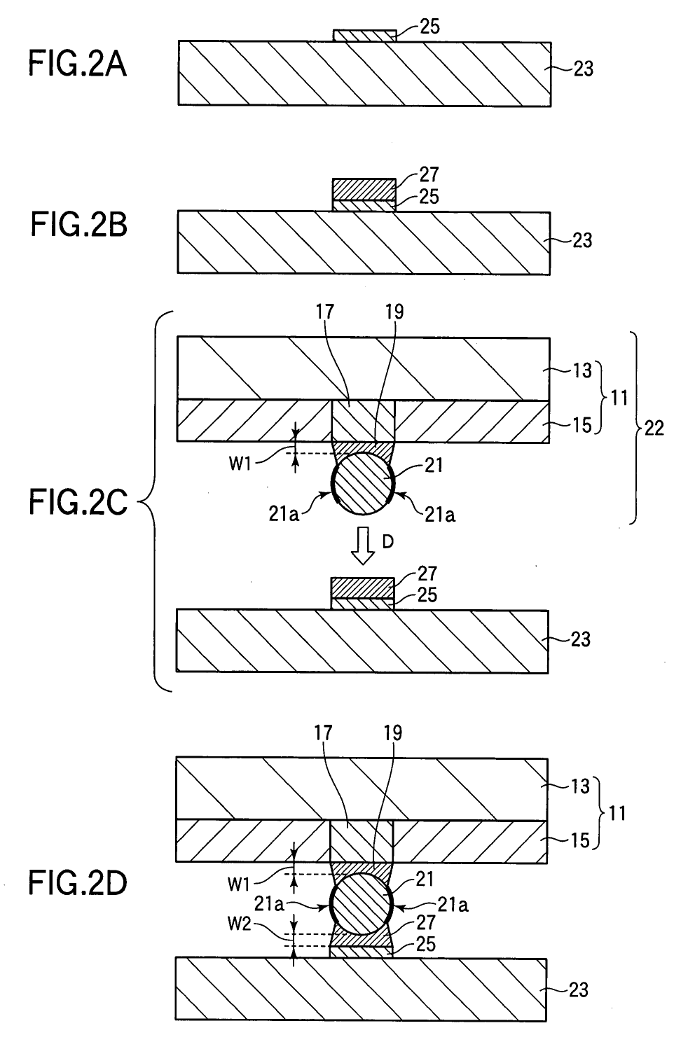

FIGS. 2A-2D are cross-sectional views illustrating fifth to eighth stages, respectively, of the method for manufacturing a semiconductor device of the second embodiment.

At the fifth stage (FIG. 2A), a printed circuit board 23 having a second terminal pad 25 on its upper surface is prepared.

The printed circuit board 23 may be any conventional printed circuit board (PCB). The printed circuit board 23 includes a second terminal pad 25 on its upper surface. Just like the first terminal pad 17 of the first embodiment, the second terminal pad 25 is formed of an electrically conductive metal, e.g., Cu. The upper surface of the second terminal pad 25 is covered with an oxide film (not shown) resulting from the reaction of the metal material of the second terminal pad 25 with the oxygen in the air.

At the sixth stage (FIG. 2B), a second solder layer 27 is formed on the upper surface of the second terminal pad 25, thereby preparing a structure in FIG. 2B.

Just as in the first solder layer 19 of the first embodiment, the second solder layer 27 may be formed by applying a solder paste using a conventional printing technique. This solder paste is a mixture of approximately 10 by weight percent of a flux, several percent by weight of rosin, approximately 1 by weight percent of an activator, several percent by weight of an alcoholic solvent, and the remaining percent by weight of solder.

The flux in the solder paste serves to remove the oxide film formed on the first terminal pad 25, facilitating bonding of the second solder layer 27 to the second terminal pad 25. The solder is, for example, a Sn—Ag—Cu solder, and preferably contains by 96.5 by weight percent of Sn, 3.0 by weight percent of Ag, and 0.5 by weight percent of Cu. The proportions expressed in weight percent should meet the following requirements.
(1) The metal ball 21 and the second terminal 25 are electrically connected in the succeeding seventh and eighth stages.
(2) The flux removes the oxide film to promote metallurgical bonding of the second solder layer 27 to the second terminal pad 25.

The above materials contained in the solder paste may be combined in any proportions as long as the aforementioned requirements are met.

Adjusting the amount of the solder paste allows adjustment of the thickness of the second solder layer 27. At the seventh stage, the second solder layer 27 is formed to have a thickness such that when the semiconductor device and the printed circuit board are subjected to the reflow process at the eight stage (FIG. 2D), an intermetallic compound fills an area W2 where heat stress is concentrated, e.g., an area into which cracks in the second solder layer 27 may propagate. The area W2 is where the metal ball is closest to the top surface of the second terminal pad 25. The amount of the second solder layer 27 should be adjusted such that the thickness of the intermetallic compound is preferably a maximum of 10 μm in the area W2. A thickness not more than 10 μm ensures that the intermetallic compound fills the area into which cracks in the second solder layer 27 may propagate. However, the thickness may deviate from 10 μm as long as the aforementioned requirements (1) and (2) are met.

At the seventh stage, a metal ball 21 is mounted in a direction shown by arrow D onto the second solder layer 27 (FIG. 2C).

A semiconductor device 22 at the seventh stage is the one manufactured through the first to fourth stages of the first embodiment. In other words, the semiconductor device 22 includes the metal ball 21 (FIG. 1D) on the first terminal pad 17 formed on the upper surface of the pellet 11, the metal ball 21 being bonded to the first terminal pad 17 with an intermetallic compound filling the area W1 between them. The thickness of the intermetallic compound is a maximum of 10 μm in the area W1 where the metal ball 21 is closest to the first terminal pad 17.

The semiconductor device 22 is positioned face down above the printed circuit board 23 such that the first terminal pad 17 and the metal ball 21 on the semiconductor device 22 face the second terminal pad 25 on the printed circuit board 23. The semiconductor device 22 is placed on the printed circuit board 23 such that the metal ball 21 sits on the second solder layer 27 formed on the printed circuit board 23.

At the eighth stage, the second solder layer 27 is reflowed to form metallurgical bonding (i.e., intermetallic compound) between the metal ball 21 and the second terminalpad 25, thereby forming a structure in FIG. 2D.

Just as the heat treatment at the fourth stage of the first embodiment, the second solder layer 27 may be reflowed using a conventional technique. The temperature and the amount of time for the reflow process may be selected in accordance with the melting point of the solder paste that forms the second solder layer 27.

After the reflow process, the second solder layer 27 is cooled to solidify again. The heating process and subsequent solidification of the second solder layer 27 form metal lurgical bonding of the metal ball 21 to the second terminal pad 27.

As described previously, the thickness of the second solder layer 27 is adjusted at the sixth stage. The resulting thickness of the second solder layer 27 is such that the intermetallic compound fills the area W2 into which cracks in the solder layer apt to propagate. Specifically, the thickness of the intermetallic compound is a maximum of 10 μin the area W2 where the metal ball 21 is closest to the second terminal pad 25.

As described above, the metal ball 21 on the semiconductor device 22 is bonded to the second terminal pad 25 on the printed circuit board with the second solder layer 27 positioned between them. The thickness of the intermetallic compound may be the same regardless of the size of the semiconductor device. The solder layers of the mounting construction of the second embodiment are such that an intermetallic compound fills an area where heat stress is concentrated, i.e., an area into which the cracks in the first solder layer 19 may propagate. It is to be noted that the thickness W1 of the first solder layer is a maximum of 10 μm in an area in which the metal ball 21 is closest to the first terminal pad 17, and that the thickness W2 of the second solder layer 27 is a maximum of 10 μm in an area in which the metal ball 21 is closest to second terminal pad 25.

The metal ball 21 is hard and has a surface area 21a exposed, i.e., not covered with solder. The surface area 21a extends all around the metal ball 21 and isolates the first solder layer from the second solder layer, preventing the first solder layer and the second solder layer from being bridged by solder. This is also effective in retarding propagation of the cracks between the first solder layer 19 and the second solder layer 27, so that when the mounting construction is subjected to heat stress due to turn-on and turn-off of the electronic assembly, propagation of the cracks in the first solder layer 19 and the second solder layer 27 is retarded. The reliability of the mounting construction for semiconductor devices may be improved by the reliable bonding of the solder to the terminal pad of the second embodiment.

At the sixth stage (FIG. 2B), the second solder layer 27 is formed on the upper surface of the second terminal pad 25. At the seventh stage (FIG. 2C), the metal ball 21 of the semiconductor device 22 is mounted on the second solder layer 27. This semiconductor device 22 is one manufactured in the first embodiment. By adjusting the amount of solder paste for the second solder layer 27, the thickness of the intermetallic compound may be the same regardless of the size of the semiconductor device 22 and the mounting construction, so that the metal ball 21 is present in an area into which heat stress is concentrated and into which the cracks in the second solder layer 27 propagate due to heat stress.

Thus, when the semiconductor device 22 is subjected to heat stress during the reflow process performed at the eighth, stage (FIG. 2D), the intermetallic compound fills an area into which the cracks in the first solder layer 19 and the second solder layer 27 may propagate, retarding the propagation of the cracks.

The second embodiment has been described in terms of a pellet 11 in a CSP package. The method of manufacturing a semiconductor device of the second embodiment may also be applied to a semiconductor structure not having the resin layer 15, for example, a flip-chip type pellet.

The method for mounting the semiconductor device on a circuit board will be summarized as follows:

Step 1: A pellet 11 is prepared which includes a first terminal pad 17 formed on a surface of the pellet.

Step 2: A first solder layer 19 is formed on the first terminal pad 17.

Step 3: A metal ball 21 is placed on the first solder layer 19.

Step 4: The pellet 11 is subjected to a reflow process such that the metal ball 21, the first solder layer 19, and the first terminal pad 17 react with one another to form an intermetallic compound that fills in an area between the metal ball 21 and the first terminal pad 17.

Step 5: A circuit board 23 is prepared which includes a second terminal pad 25 formed on a surface of the circuit board 23.

Step 6: A second solder layer 27 is formed on the second terminal pad 25.

Step 7: The semiconductor device is placed on the circuit board 23 such that the metal ball 21 is in contact with the second solder layer 27.

Step 8: The circuit board 23 and the semiconductor device with the metal ball 21 on it are subjected to a reflow process such that the metal ball 21, the second solder layer 27, and the second terminal pad 25 reacting with one another to form an intermetallic compound that fills in an area between the metal ball 21 and the second terminal pad 25.

At step 4, the thickness of the first solder layer is selected such that the distance between the metal ball 21 and the first terminal pad 17 is less than or equal to 10 μm in the area in which the metal ball 21 is closest to the first terminal pad 17.

At step 6, the thickness of the first solder layer is selected such that the distance between the metal ball 21 and the first terminal pad 17 is less than or equal to 10 μm in the area in which the metal ball 21 is closest to the first terminal pad 17.

What is claimed is:

1. A semiconductor device, comprising:
a base;
a first terminal pad formed on the base;
a first solder layer formed on the first terminal pad; and
a metal ball mounted to the first terminal pad by the first solder layer, the metal ball has a first surface covered with the first solder layer;
wherein a distance between the metal ball and the first terminal pad is less than or equal to 10 μm in a first area in which the metal ball is closest to said first terminal pad.

2. The semiconductor device according to claim 1, wherein an intermetallic compound is formed in the first area.

3. The semiconductor device according to claim 2, wherein the metal ball, the first solder layer, and the first terminal pad react with one another to form the intermetallic compound.

4. The semiconductor device according to claim 3, wherein the first solder layer is an Sn—Ag—Cu solder, and the first terminal pad and the metal ball are formed of copper, wherein the intermetallic compound is Cu₆Sn₅.

5. The semiconductor device according to claim 3, wherein said metal ball is formed of nickel (Ni).

6. The semiconductor device according to claim 3, wherein said metal ball is formed of tungsten (W).

7. The semiconductor device according to claim 1, wherein said metal ball (21) has a degree of purity higher than 99.99%.

8. A mounting structure for a semiconductor device, comprising:
a base having a first terminal pad;
a circuit board having a second terminal pad;
a first solder layer formed on the first terminal pad;
a second solder layer formed on the second terminal pad; and
a metal ball positioned between the base and the circuit board, the metal ball mounted to the first terminal pad by the first solder layer and to the second terminal pad by the second solder layer, the metal ball has a first surface covered with the first solder layer, a second surface covered with the second solder layer and a third surface exposes a surface of the metal ball;
wherein a distance between the metal ball and the first terminal pad is less than or equal to 10 μm in a first area in which the metal ball is closest to the first terminal pad, and a distance between the metal ball and the second terminal pad is less than or equal to 10 μm in a second area in which the metal ball is closest to the second terminal pad.

9. The semiconductor device according to claim 8, wherein the metal ball, the first solder layer, and the first terminal pad react with one another to form an intermetallic compound, wherein the metal ball, the second solder layer, and the second terminal pad react with one another to form an intermetallic compound.

10. The semiconductor device according to claim 9, wherein the intermetallic compound fills in the first area and in the second area.

11. The semiconductor device according to claim 10, wherein said second solder layer is an Sn—Ag—Cu solder, and said second terminal pad and said metal ball are formed of Cu, wherein the intermetallic compound is Cu₆Sn₅.
